(19) United States
(12) Patent Application Publication
(10) Pub. No.: US 2024/0339691 A1
(43) Pub. Date: Oct. 10, 2024

(54) ASSESSING PERFORMANCE OF A BATTERY PACK THERMAL MANAGEMENT SYSTEM

(71) Applicant: GM GLOBAL TECHNOLOGY OPERATIONS LLC, Detroit, MI (US)

(72) Inventors: Miguel A. Fernandez, St. Claire Shores, MI (US); Benjamin R. Christian, Plymouth, MI (US); James E. Kettlewell, Windsor (CA); Simon J. H. Trask, Royal Oak, MI (US); Daniel F. Witting, Sterling Heights, MI (US)

(73) Assignee: GM GLOBAL TECHNOLOGY OPERATIONS LLC, Detroit, MI (US)

(21) Appl. No.: 18/296,482

(22) Filed: Apr. 6, 2023

(51) Int. Cl. H01M 10/625; H02J 7/00

(52) U.S. Cl. CPC H01M 10/625; H02J 7/00041

(57) ABSTRACT

A method for assessing performance of a thermal management system configured for thermally managing a battery pack of an electric vehicle. The method may include determining a voltage response of the battery pack while subjected to a test load and generating a thermal assessment for the thermal management system based on the voltage response and/or resistivity values derived therefrom.

### INTRODUCTION

The disclosure relates to assessing performance of thermal management systems, such as but not necessarily limited to assessing performance of thermal management systems configured for cooling a battery pack of an electric vehicle.

An electric vehicle, machine, equipment, or other device may rely upon a battery pack to selectively supply and store electrical power. The battery pack may operate at relatively high temperatures such that it may be desirable to include a thermal management system for cooling and otherwise managing heat dissipation and related thermal activities. Some thermal management systems may include cold plates, heat sinks, coolant systems, and other componentry integrated with or otherwise assembled with the battery pack. The integration of the thermal management system may make it challenging or difficult to assess its performance without disassembling the battery pack and/or undertaking costly and time consuming investigations, such as with computed tomography (CT) scans.

### SUMMARY

One non-limiting aspect of the present disclosure relates to assessing performance of a thermal management system, such as but not necessarily limited to assessing performance of a thermal management system configured for thermally managing a battery pack of the type having a plurality of battery cells configured for selectively storing and supplying electrical power. The assessment may be based on deriving resistivity values for the battery pack according to a voltage response of the battery cells when subjected to a test load, and thereafter, relating the resistivity values to performance of the thermal management system. The voltage response may be determined according to voltage measurements taken across the battery cells using electronics onboard the battery pack so as to permit an assessment of the thermal management system without having to disassemble the battery pack and/or without having to employ CT scans or other costly or time consuming investigations.

One non-limiting aspect of the present disclosure relates to a method for assessing performance of a thermal management system configured for thermally managing a battery pack of an electric vehicle. The method may include determining a test load to be applied to a plurality of battery cells included as part of the battery pack, determining a voltage response of the battery cells while subjected to the test load, and generating a thermal assessment based on the voltage response. The thermal assessment may represent capabilities of the thermal management system to thermally manage the battery pack.

The method may include generating a resistivity profile for the battery cells according to the voltage response and generating the thermal assessment to indicate a wet-out state for the battery pack to be desirable when the resistivity profile is within a resistivity response range and undesirable when outside of the resistivity response range, the wet-out-state characterizing thermal coupling via a thermal interface material (TIM) between the battery cells and a cold plate of the battery pack.

The method may include the voltage response including a voltage measurement for each of the battery cells to represent voltage sensed across the corresponding battery cell while subjected to the test load.

The method may include the thermal assessment indicating performance of the thermal management system to be desirable when each of the voltage measurements are within the voltage response range and to be undesirable when at least one of the voltage measurements are outside of the voltage response range.

The method may include the thermal assessment indicating performance of the thermal management system to be outside of a desired range in response to a voltage delta between one or more of the voltage measurements exceeding a threshold.

The method may include the thermal assessment indicating performance of the thermal management system to be desirable when each of the voltage measurements are within a voltage response range and undesirable when one or more of the voltage measurements are outside of the voltage response range.

The method may include thermally cycling the battery pack prior to applying the test load. The thermal cycling may include heating or cooling the battery pack from a first temperature to a second temperature. The method may include applying the test load while a temperature of the battery pack is within a predefined range of the second temperature.

The method may include controlling coolant flow through a cold plate of the battery pack to thermally cycle the battery pack.

The method may include controlling coolant flow through an auxiliary cold plate thermally coupled to a cold plate of the battery pack to thermally cycle the battery pack.

The method may include, before applying the test load, verifying the battery pack has reached the second temperature with a thermistor of the battery pack. The thermistor may be configured for measuring the temperature according to a temperature varying resistive element.

The method may include applying the test load and measuring the voltage response with a cell monitoring unit (CMU) of the battery pack.

The method may include applying the test load and measuring the voltage response as part of an end-of-line test performed before the battery pack is installed within the electric vehicle.

The method may include applying the test load and measuring the voltage response as part of an in-vehicle test performed after the battery pack is installed within the electric vehicle.

The method may include generating the test load as a direct current (DC) pulse.

The method may include generating the DC pulse with an amplitude of approximately 300-500 amperes and a duration of approximately 15-45 seconds.

One non-limiting aspect of the present disclosure relates to a method for assessing performance of a thermal management system configured for thermally managing a battery pack. The method may include determining a test load to be applied to one or more battery groups included as part of the battery pack where each of the battery groups includes one or more battery cells, determining a voltage response of the battery groups while subjected to the test load, and generating a thermal assessment based on the voltage response. The thermal assessment may include a performance of the thermal management system to be desirable when the voltage response is within a voltage response range and to be undesirable when the voltage responses outside of the voltage response range.

The method may include thermally cycling the battery pack prior to applying the test load. The thermal cycling heating or cooling the battery pack from a first temperature to a second temperature. The method may include applying the test load while a temperature of the battery pack is within a predefined range of the second temperature.

The method may include the voltage response including a voltage measurement for each of the battery cells. The voltage measurement may represent voltage sensed across the corresponding battery cell while subjected to the test load. The method may include determining a delta voltage according to a difference between a maximum measurement and a minimum measurement of the voltage measurements, and determining the performance to be desirable when the voltage delta is within the voltage response range and determining the performance to be undesirable when the voltage delta is outside of the voltage response range.

The method may include the voltage response including a voltage measurement for each of the battery cells to represent voltage sensed across the corresponding battery cell while subjected to the test load and determining the performance to be desirable when each of the voltage measurements are within the voltage response range and determining the performance to be undesirable when at least one of the voltage measurement is outside of the voltage response range.

One non-limiting aspect of the present disclosure relates to a method for assessing performance of a thermal management system configured for thermally managing a battery pack. The battery pack may include a thermal interface material (TIM) for thermally coupling the battery pack to a cold plate. The method may include determining a voltage response of the battery pack while subjected to a test load, generating a resistivity profile for the battery pack according to the voltage response, and indicating a wet-out state for the battery pack to be desirable when the resistivity profile is within a resistivity response range and undesirable when outside of the resistivity response range, the wet-out-state characterizing thermal coupling of the TIM.

These features and advantages, along with other features and advantages of the present teachings, are readily apparent from the following detailed description of the modes for carrying out the present teachings when taken in connection with the accompanying drawings. It should be understood that even though the following figures and embodiments may be separately described, single features thereof may be combined to additional embodiments.

### BRIEF DESCRIPTION OF THE DRAWINGS

The accompanying drawings, which are incorporated into and constitute a part of this specification, illustrate implementations of the disclosure and together with the description, serve to explain the principles of the disclosure.

FIG. 1 illustrates an electric vehicle having a battery pack in accordance with one non-limiting aspect of the present disclosure.

FIG. 2 illustrates a perspective view of the battery pack in accordance with one non-limiting aspect of the present disclosure.

FIG. 3 illustrates a cross-sectional view of the battery pack in accordance with one non-limiting aspect of the present disclosure.

FIG. 4 illustrates a comparison graph in accordance with one non-limiting aspect of the present disclosure.

FIG. 5 illustrates an auxiliary cold plate in accordance with one non-limiting aspect of the present disclosure.

FIG. 6 illustrates a flowchart of a method for assessing performance of a thermal management system in accordance with one non-limiting aspect of the present disclosure.

FIG. 7 illustrates a schematic diagram of a test load process in accordance with one non-limiting aspect of the present disclosure.

FIG. 8 illustrates a flowchart for a supplemental process in accordance with one non-limiting aspect of the present disclosure.

### DETAILED DESCRIPTION

As required, detailed embodiments of the present disclosure are disclosed herein; however, it is to be understood that the disclosed embodiments are merely exemplary of the disclosure that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present disclosure.

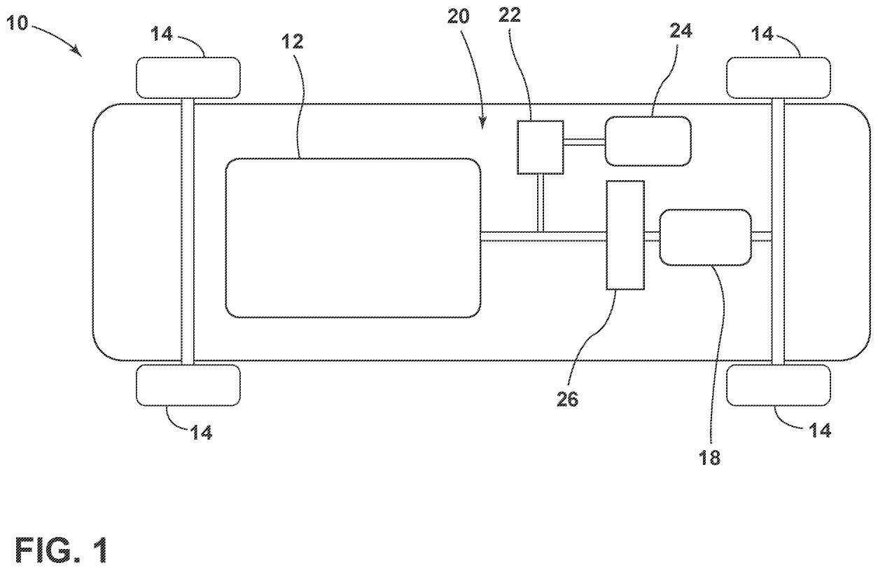

FIG. 1 illustrates an electric vehicle 10 having a battery pack 12 in accordance with one non-limiting aspect of the present disclosure. The battery pack 12 may be predominately described as incorporated within the illustrated, automobile type of electric vehicle 10, however, the present disclosure fully contemplates the battery pack 12 being incorporated with other types of devices, including locomotives, marine vessels, airplanes, etc. The electric vehicle 10 may include a plurality of wheels 14, with a portion of the wheels 14 being configured for propulsion with an electric motor 18. The electric motor 18 may be included as part of an electrical power distribution system 20 configured for at least partially relying upon electrical power being stored at and supplied from the battery pack 12. The power distribution system 20 is shown for non-limiting purposes to facilitate charging and discharging electrical power to and from the battery pack 12. The power distribution system may include a DC-to-DC converter 22 for exchanging electrical power with one or more vehicle systems and other electrical loads 24 included onboard the vehicle 10. The power distribution system 20 may further include an AC-to-DC converter or other driver electronics 26 for distributing and otherwise controlling electrical power consumption and operation of the electric motor 18.

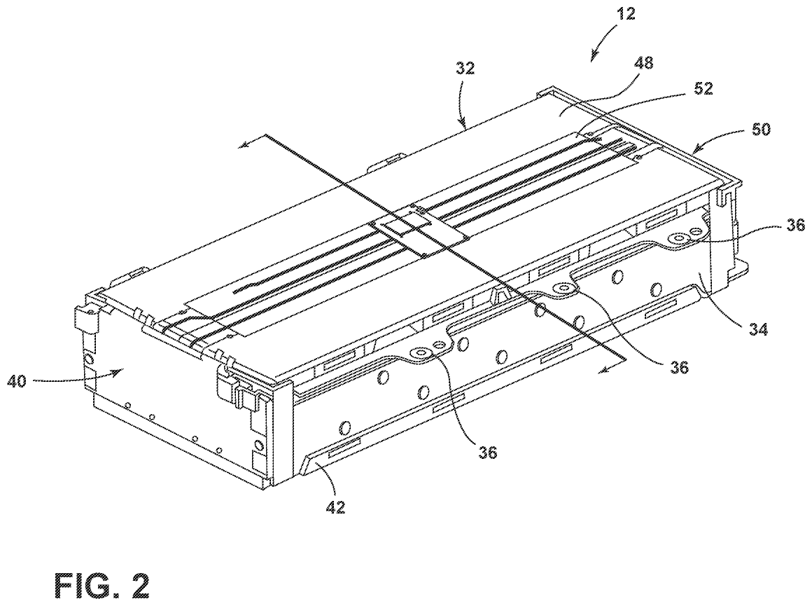

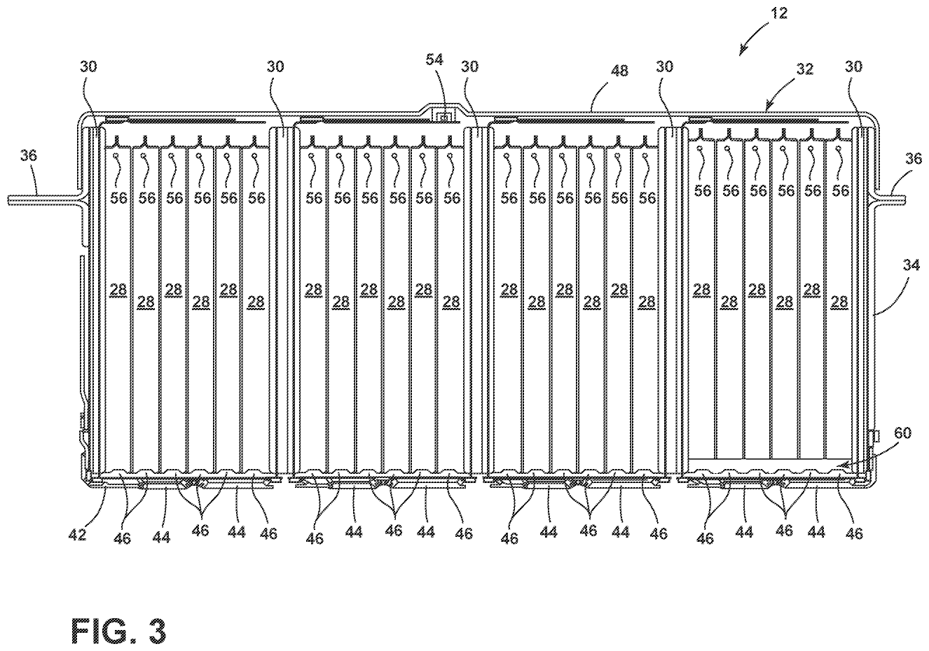

FIG. 2 illustrates a perspective view of the battery pack 12 in accordance with one non-limiting aspect of the present disclosure. FIG. 3 illustrates a cross-sectional view of the battery pack 12 in accordance with one non-limiting aspect of the present disclosure. The battery pack 12 may include a plurality of battery cells 28 configured for storing and supplying the electrical power. The battery cells 28 may be pouch-type, Li-ion polymer battery cells 28 stacked in a side-by-side facing relation with one another and connected in parallel or series, with the vehicle 10 optionally including multiple battery packs 12 a similar construction. While shown as a graphite-based, Li-ion “pouch cell” battery, the battery cells 28 may be adapted to other chemistries and other constructions and/or other types of electrical devices, including cylindrical and prismatic battery cell 28 configurations. Each battery cell 28 may be constructed with an outer battery casing, which is represented in the drawings by an envelope-like pouch, having an electrical terminal extending therefrom at each end. The casing may be formed of an aluminum sheet or foil, or other suitable material, both sides of which may be coated with a polymeric material that insulates the metal from the cell elements and from an adjacent cell(s).

A plurality of thermal barriers or expansion-compensating foam 30 may be disposed between a portion of the battery cells 28 to divide and thermally insulate stacks of the battery cells 28 from each other and allow for expansion and contraction of the cells 28 during operation. FIG. 3 illustrates an exemplary configuration for the battery cells 28 whereby the thermal barriers may be used to separate battery cells 28 into four ministacks, with each ministack including two battery groupings of three battery cells 28 each. The corresponding configuration may include eight cell groups with each cell group including three cells 28 connected in parallel in a manner that may be characterized as a 3P8S configuration. The illustrated configuration of the battery cells 28 is presented for exemplary and non-limiting purposes as the present disclosure fully contemplates the battery pack 12 including more or less battery cells 28 arranged in different configurations, optionally with the circuitry and/or componentry associated therewith connecting the battery cells 28 in series and/or parallel with each other according to a wide variety of connection methodologies.

The battery pack 12 may be configured to store the battery cells 28 inside a protective, electrically insulating battery housing module 32. The housing module 32 may be a rigid, multi-part construction assembled from a flanged housing 34 with a pair of elongated sidewalls and endwalls that project generally orthogonally from the base. Once properly arranged and mounted, the stacked battery cells 28 may be supported on the housing base and sandwiched between the module sidewalls. Mounting brackets 36 may extend transversely from the sidewalls to facilitate mounting within the vehicle. A thermal management system 40 may be included as part of or operational with the battery pack 12 to facilitate cooling and otherwise managing heat dissipation and related thermal activities. The thermal management system may include a cold plate 42 or other heat sink mounted underneath the stacked battery cells 28 to selectively transfer heat out of the battery pack 12. The cold plate 42 may include one or more coolant channels 40 within an interior thereof that circulate a coolant fluid received via coolant ports. A thermal interface material (TIM) 46 may be included to facilitate thermally coupling the battery cells 28 to the cold plate 42.

The battery pack 12 may include an integrated interconnect board (ICB) assembly 48 configured to align and electrically interconnect the battery cells 28. The ICB assembly 48 may be mounted on top of the base to provide a protective C-shaped jacket that may be generally defined by a central cover with a pair of sidewall flanges and a pair of endwall flanges. The battery pack 12 may include a cell monitoring unit (CMU) 50 or other computation module configured for controlling the battery pack 12 and/or thermal management system 40. The CMU 50 may be mounted between the endwall plates and one of the opposed endwalls. The CMU 50 may cooperate with and electrically connect to a flexible printed circuit board (PCB) 52 mounted to the central cover. One or more thermistors 54 may be operational with the CMU 50 to measure temperature of the battery pack 12, such as according to resistive variances of an included temperature very resistive element. One non-building aspect of the present disclosure contemplates including a plurality of voltage sensors 56 to sense current and/or voltage across the battery cells 28.

The CMU 50 may be comprised of a printed circuit board, a flexible circuit board, and/or other componentry capable of calculating or otherwise determining the values and information contemplated herein. The CMU 50, for example, may be configured as an Application Specific Integrated Circuit (ASIC) having capabilities commensurate with those described herein. The CMU 50 may include a computer readable storage medium having a plurality of non-transitory instructions stored thereon, which when executed with associated processor, may be sufficient to facilitate or otherwise enable the operations and processes described herein. The vehicle 10 may include a wide variety of systems and subsystems for a correspondingly wide variety of operational capabilities, which may be controlled or predicated based at least in part on a state of health (SOH), a state of charge (SOC), or other electrical capability of the battery cells 28 to store and supply electrical power.

One non-limiting aspect of the present disclosure contemplates the CMU 50 being configured for assessing performance of the thermal management system 40, such as according to a software, program, or other logically executing construct. The CMU 50, for example, may include a computer-readable storage medium having a plurality of non-transitory instructions stored thereon, which when executed with a processor, may be sufficient for generating a thermal assessment for the thermal management system 40. The thermal assessment may be used for representing capabilities of the thermal management system 40 to thermally manage the battery pack 12, i.e., a capability of the thermal management system 40 to facilitate cooling or other thermal activities for the battery pack 12. The CMU 50 may be configured to generate the thermal assessment as an end-of-line test and/or an in-vehicle test. The end-of-line test may correspond with the CMU 50 generating the thermal assessment prior to the battery pack 12 being installed within the vehicle. The in-vehicle test may correspond with the CMU 50 generating the thermal assessment after the battery pack 12 has been installed within the vehicle.

The thermal assessment may be generated to determine whether a sufficient wet-out has occurred between the battery cells 28 and the cold plate 42. The wet-out may relate to the quality of a thermal coupling between the battery cells 28 and the cold plate 42 created with the TIM 46. To maximize thermal transfer and otherwise facilitate dissipating heat from the battery cells 28 to the cold plate 42, a sufficient amount of contact may be required between the TIM 46 and the battery cells 28 and cold plate 42. The battery pack 12 may be assembled in a manufacturing process whereby the TIM 46 material may be applied to the cold plate 42 whereafter the battery cells 28 and related componentry may be adhered or fastened thereto. The TIM 46 may be applied to the cold plate 42 as a liquid, gel, grease, or other type of material capable of flowing or as a pad, insert or other material capable of being compressed or otherwise changing in shape or size when pressed with the battery cells 28. FIG. 3 illustrates an exemplary scenario whereby an air gap 60 has occurred between a portion of the battery cells 28 in the TIM 46, which may occur in the event the battery cells 28 fail to adequately contact the TIM 46, either due to a lack of contact or the amount of contacting being below a desired level.

Once the battery cells 28 are attached to the cold plate 42, the TIM 46 material may be hidden and incapable of being easily inspected such that a visual assessment of the wet-out may require disassembly of the battery pack 12 and/or employing CT scans or other costly or time consuming investigations. One non-limiting aspect of the present disclosure contemplates generating a thermal assessment for the wet-out without having to disassemble or otherwise undertake costly or time consuming investigations by instead assessing a voltage response of the battery cells 28 when subjected to a test load. The thermal assessment described herein may relate the voltage response to resistivity characteristics representative of thermal properties between the battery cells 28 and the cold plate 42 such that the resistivity characteristics may be compared to a resistivity profile to identify characteristics reflective of the airgap 60 and/or other deficiencies with the TIM 46 wet-out. The voltage sensors 56 may be configured to determine voltage across each of the battery cells 28 subjected to a test pulse, whereafter, a resistivity of the corresponding battery cells 28 may be calculated.

The resistivity calculated for the battery cells 28 may be related to thermal properties associated with dissipating heat from the battery cell 28 to the cold plate 42 due to a relationship between resistivity of the battery cells 28 and battery cell 28 temperature. The resistivity of the battery cells 28 may increase as the battery cells 28 cool down such that this relationship between cooling and resistivity may be used to identify the battery cells 28 having improper or inadequate wet-out due to those battery cells 28 having a lower resistivity than the battery cells 28 with adequate wet-out. In other words, when thermally cycled, the battery cells 28 having adequate wet-out may cool faster or maintain a lower temperate than the battery cells 28 with inadequate wet-out such that the battery cells 28 with adequate wet-out may have a greater resistivity compared to the battery cells 28 with inadequate wet-out. The differences in resistivity between the battery cells 28 may be determined based on differences in the voltage measurements taken thereacross such that the thermal assessment contemplated herein may be used to assess the wet-out for each battery cell 28 based on relative differences in resistivity to the other battery cells 28, and beneficially, without having to disassemble or otherwise visually inspect the TIM 46.

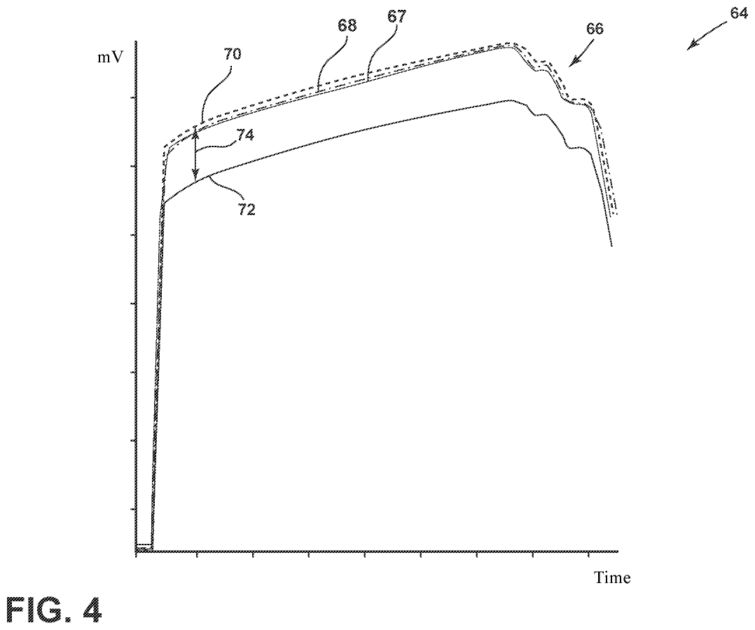

FIG. 4 illustrates a comparison graph 64 in accordance with one non-limiting aspect of the present disclosure. The comparison graph 64 may be used to compare voltage responses 66 (graphed lines) of the battery cells 28 to each other, i.e., to compare voltage measurements taken across the battery cells 28 to each while subjected to a test load. The vertical axis may be incremented in millivolts, optionally with the voltage sensors 56 having capabilities to measure the voltage at the millivolt level, e.g., 1-7 mV. The horizontal axis may be incremented according to time. The comparison graph 64 is shown for exemplary purposes as including a plurality of voltage responses 67, 68, 70, 72 for each of the ministacks. The test load in accordance with one non-limiting aspect of the present disclosure may be administered using electrical power available onboard the vehicle 10, such as when performing an in-vehicle test, and/or using electrical power available from sources offboard the vehicle, such as when performing an end-of-line test. The test load may correspond with a direct current (DC) pulse having an amplitude of approximately 300-500 amperes and a duration of approximately 15-45 seconds. A test load of this amplitude and duration may be beneficial in facilitating the thermal assessment contemplated herein without overly stressing the battery pack 12 or causing the battery pack 12 to heat or otherwise experience the stresses that may arise with test load of a longer duration or significance.

The test load may be applied equally to each of the battery cells 28, which in the illustrated comparison graph may include voltage responses 66 separated from the other voltage responses. A voltage delta 74 may be illustrated to coincide with a voltage differential between a maximum voltage response 70 and a minimum voltage response 72, however, additional delta values or differences between the voltage responses 66 may be calculated to generate the comparison graph 64. The voltage delta 74, which is shown to be approximately 42 millivolts (mV), may be useful to assess whether one or more of the battery cells 28, battery groups, or ministacks may be producing voltage responses 66 differing from the other voltage responses 66. A difference in relative voltage measurements may be reflective of the corresponding battery cells 28 cooling, heating, or otherwise dissipating heat at a rate or a degree differing from the other battery cells 28. In the event the corresponding voltage responses 66 deviate from each other beyond a predetermined amount, range, or pattern, the performance of the thermal management system 40 may be considered as undesirable and/or reflective of a situation where battery cells 28 may be inadequately cooling.

The voltage measurements reflected in the comparison graph 64 may be related to resistivity of the corresponding battery cells 28 based on Ohm's law. With the voltage sensors 56 measure voltage across the battery cells 28 and the test load, i.e., the DC pulse being known, the resistivity of each battery cell 28 during the test load may be calculated. As noted above, a relationship may exist between resistivity of the battery cells 28 and the cooling thereof, i.e., the battery cells 28 experiencing greater cooling may exhibit a greater resistivity than the battery cells 28 exhibiting less cooling. The test load may be configured to test the battery cells 28 without overly heating the battery pack 12 such that it may be desirable to thermally cycle the battery pack 12 prior to application of the test load. The thermal cycling may be used to increase or decrease a temperature of the battery pack 12 from a current temperature to test temperature in order to thermally induce a resistivity variance between the battery cells 28. The thermal cycling of battery pack 12 in this manner from a first temperature to a second temperature may be beneficial in magnifying differences in the TIM 46 thermal coupling, i.e., the adequacy thereof, such that battery cells 28 having inadequate TIM 46 contact may thermally cycle differently than the battery cells 28 having adequate TIM 46 contact, which may then be correspondingly represented with differing voltage responses and resistivity calculations.

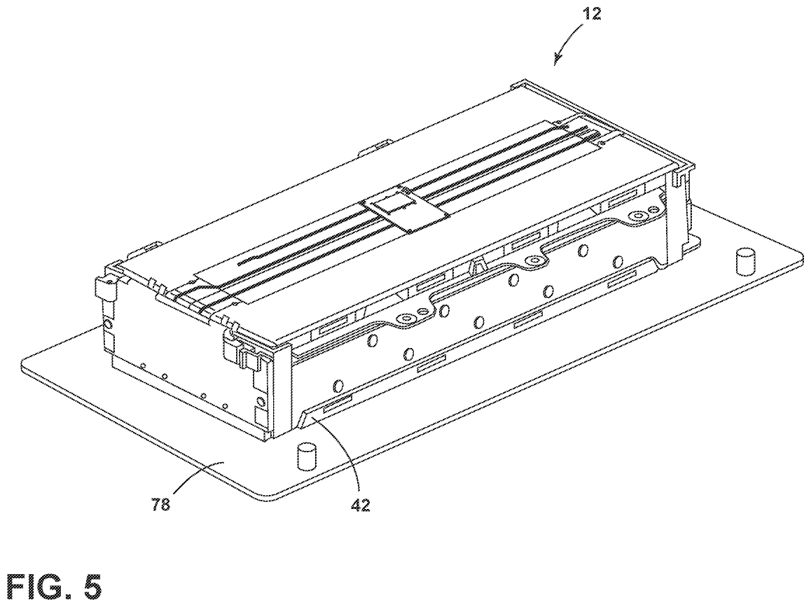

FIG. 5 illustrates an auxiliary cold plate 78 in accordance with one non-limiting aspect of the present disclosure. The auxiliary cold plate 78 may be thermally coupled with the battery pack cold plate 42 to assist in thermally cycling the battery pack 12 in cooperation with the battery pack cold plate 42 and/or independently thereof, i.e., the auxiliary cold plate 78 may be operated in place of the battery cold plate 42. The battery pack cold plate 42 may include a plurality of internal channels 44, pathways, etc. to facilitate circulating coolant fluid therethrough, which may be used to facilitate dissipating heat from the battery pack 12. Once assembled, the channels 44 and other internal structures of the battery pack cold plate 42 may be relatively inaccessible such that the inspection thereof may suffer from similar challenges and difficulties as that described with respect to the wet-out, at least in so far as being practically incapable of visual inspection without disassembly or otherwise undertake costly or time consuming activities. As described below in more detail, the auxiliary cold pack 78 may be utilized in cooperation with the battery pack cold plate 42 to differentiate thermal inadequacies of the cold plate 42 from thermal inadequacies of the TIM 46.

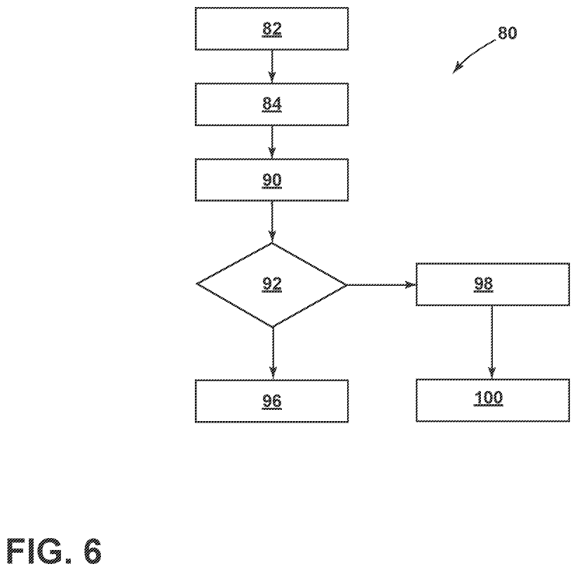

FIG. 6 illustrates a flowchart 80 of a method for assessing performance of a thermal management system 40 in accordance with one non-limiting aspect of the present disclosure. The method is predominantly described with respect to assessing performance of a thermal management system 40 configured for thermally managing a battery pack 12 of an electric vehicle 10 for non-limited purposes as the present disclosure fully contemplates the thermal assessment described herein being useful in other applications and with other devices. Block 82 relates to a thermal cycling process whereby the battery pack 12, or more specifically the thermal conductivity between the battery cells 28, TIM 46, and cold plate 42, may be cycled from a first temperature to a second temperature. The thermal cycling may include increasing or decreasing a temperature of the battery pack 12 for purposes of maximizing resistivity differences across the battery cells 28. The thermal cycling may be performed by cold soaking the battery pack 12 to a predefined temperature, such as but not necessarily limited to zero degrees Celsius, and thereafter preconditioning the battery pack 12 to a higher or lower temperature, such as but not necessarily limited to increasing or decreasing the battery temperature by 18 degrees Celsius.

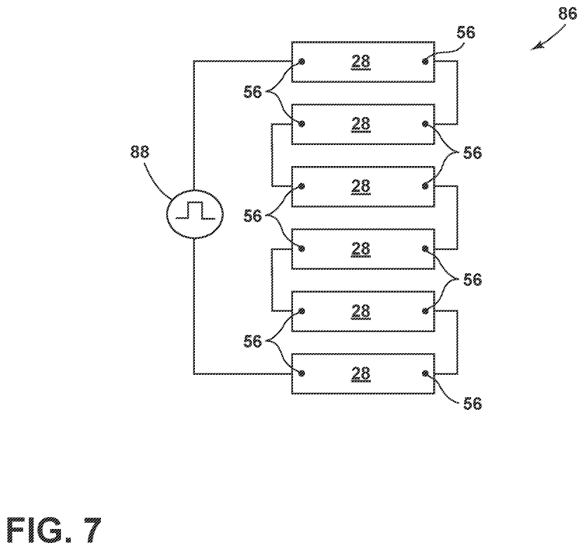

Block 84 relates to a test load process. FIG. 7 illustrates a schematic diagram 86 of the test load process. The test load process may include determining and applying a test load 88 to the battery cells 28 once adequately thermally cycled. The test load 88 may be applied by or through corresponding controls implemented with the CMU 50. The voltage sensors 56 associated with each battery cell 28 may be used to generate voltage measurements during the test load process. Returning to FIG. 6, Block 90 relates to a voltage response process for determining voltage responses 66 of the battery cells 28 while subjected to the test load 88. The voltage responses 66 may include the CMU 50 relying upon the voltage sensors 56 to determine voltage measurements for the corresponding battery cells 28 while subjected to the test load 88. Block 92 relates to a thermal assessment process whereby the CMU 50 may generate a thermal assessment for the thermal management system 40. The thermal assessment may be used for representing capabilities of thermal management system 40 to thermally manage the battery pack 12. One non-limiting aspect of the present disclosure contemplates the thermal assessment indicating the thermal management system 40 to be performing desirability or undesirably depending on the voltage responses 66.

Block 96 relates to a pass or desirable assessment being determined in the event the thermal assessment indicates desirable performance, i.e., that the voltage responses 66 fall within a desired voltage response range. Block 98 relates to a non-pass or undesirable assessment process being determined in the event the thermal assessment indicates undesirable performance, i.e., that one or more of the voltage responses 66 fail to fall within a desired voltage response range. The desirability and undesirability of the voltage responses 66 may be based on a voltage delta 74 between one or more of the voltage responses 66 and/or relative to absolute or predefined voltage levels. A relative difference in voltage responses 66 across the battery cell 28 may be indicative of unequal or inadequate heat dissipation as it may be expected that each battery cell 28 experiences a relatively similar amount of heat dissipation when the thermal management system 40 is operating desirably. The voltage measurements may be related to resistivity calculations for the battery cells 28 such that values for voltage and/or resistivity may be utilized to determine whether the battery cells 28 are properly dissipating heat. For a particular battery pack 12 construction and characteristics, it may be expected that each battery cell 28 will have a particular resistivity when the thermal management system 40 is operating desirably.

In the event the thermal management system 40 is determined to be performed undesirably, the thermal assessment may further include a supplemental process at Block 100. The supplemental process may employ additional processes may be performed to determine whether the undesirable assessment resulted from inadequate wet-out, inadequate operation of the battery pack cold plate 42, or from inadequate performance of some other aspect of the thermal management system 40. The inadequate wet-out may result when air gaps 60 may be formed between the battery cells 28 and the TIM 46 and/or when the TIM 46 fails to provide adequate thermal conductivity between the battery cells 28 in the cold plate 42. The inadequate operation of the battery cold plate 42 may result from one or more of the cooling channels 44 being blocked or partially obstructed in a manner causing coolant to inadequately flow therethrough. The inadequate operation of other aspects of the thermal management system 40 may result from one or more of the voltage sensors 56 in accurately generating the voltage measurements, a circuit discontinuity causing the test load 88 to be applied unequally across the battery cells 28, and/or for a wide variety of other factors that may be unrelated to TIM 46 wet-out and/or coolant flow through the battery cold plate 42.

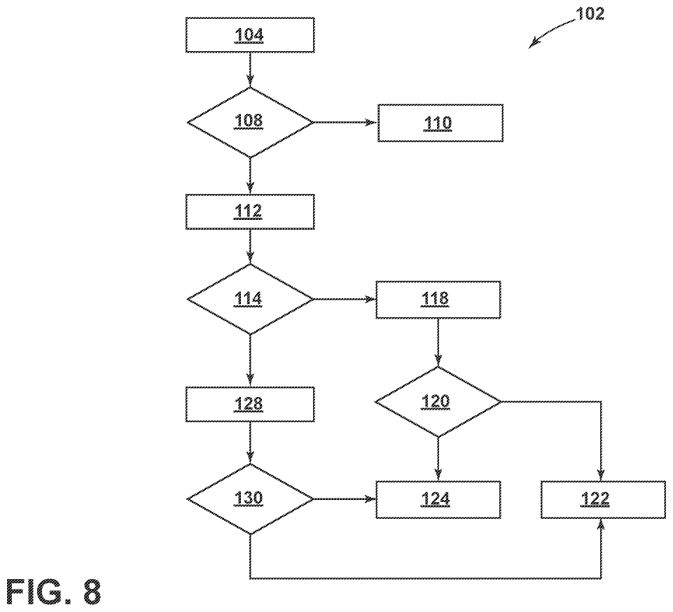

FIG. 8 illustrates a flowchart 102 for the supplemental process in accordance with one non-limiting aspect of the present disclosure. The supplemental process may be useful in determining whether the undesirable performance resulted from the TIM 46 wet-out, deficiency of the battery pack cold plate 42, or from other aspects of the thermal management system 40. Block 104 relates to a study-state process associated with allowing the battery pack 12 temperature to reach an ambient environment or to otherwise be thermally manage to a steady-stay condition for a predefined period of time. The predefined period of time may be selected so that a voltage response 66 of the battery cells 28 to the test load may be determined without the battery pack 12 having recently experienced a change in temperature. By avoiding the above described thermal cycling process, the attendant thermal changes of the TIM 46 and/or coolant flow through the channels 44 may be minimized to the point of the influences thereof being effectively canceled. In other words, once the battery pack 12 and attendant features have reached a steady-state temperature for a predefined period of time, application of the test load 88 may be insufficient for the voltage response 66 thereto to be dependent on thermally induced resistance variations of the battery cells 28.

Block 108 relates to a steady-state assessment process whereby voltage responses 66 of the battery cells 28 to the test load 88 may be determined while the battery pack 12 is at the steady-state temperature. The steady-state assessment may determine the performance to be desirable or undesirable in a similar manner to that described above with respect to the thermal assessment of Block 92, i.e., determining desirable performance when the voltage responses 66 are within a predefined range and undesirable when outside the predefined range. Block 110 relates to determining the voltage response 66 in Block 108 coinciding with undesirable performance. Because the undesirable performance resulted from the test load 88 being applied without thermally cycling the TIM 46 and battery cold plate 42, it may be assumed that the undesirable performance resulted from a source within the thermal management system 40 other than the TIM 46 wet-out and battery pack cold plate 42, e.g., from a deficiency in the voltage sensors 56, circuitry of the battery pack 12 applying the test load 88, or some other aspect of the thermal management system 40.

Block 112 relates to determining the voltage response 66 in Block 108 coinciding with desirable performance. Because the desirable performance resulted from the influence of the TIM 46 and cold plate 42 being effectively canceled due to the battery pack 12 being at the steady-state temperature, it may be assumed that the undesirable performance previously determined in Block 98 resulted from the TIM 46 wet-out or the battery pack cold plate 42. Block 114 relates to determining whether the thermal cycling performed in Block 82 was performed with assistance of the battery pack cold plate 42 or the auxiliary cold plate 78. The thermal cycling contemplated herein may be used to transition the battery pack 12 from one temperature to another temperature for purposes of applying the test load 88 shortly thereafter. The thermal cycling may include cold soaking the battery pack 12 without use of the battery pack cold plate 42 and the auxiliary cold plate 78, such as by placing the battery pack 12 in a temperature controlled environment, and thereafter preconditioning the battery pack 12 to another temperature using coolant cycled through one of the battery pack cold plate 42 and the auxiliary cold plate 78. The thermal cycling may also be performed independently by the battery pack cold plate 42 or the auxiliary cold plate 78, optionally without cold soaking.

Making a determination as to whether the undesirable performance identified in Block 98 occurred while the battery pack 12 was thermally cycled using the battery pack cold plate 42 or the auxiliary cold plate 78 may be influential in identifying whether the undesirable performance resulted from the battery pack cold plate 42 or the TIM 46 wet-out. Block 118 relates to determining the thermal cycling to have been previously undertaken with the battery pack cold plate 42. Block 120 relates to determining the thermal cycling in Block 82 to have been previously performed using the battery pack cold plate 42 and performing an auxiliary cold plate assessment. The auxiliary cold plate assessment may be used to determine voltage responses 66 of the battery cells 28 to the test load 88 after the battery pack 12 has been thermally cycled with the auxiliary cold plate 78, which may occur without controlling coolant flow through the battery cold plate 42 and/or after draining coolant from the battery pack cold plate 42. The auxiliary cold plate assessment may determine the performance to be desirable or undesirable in a similar manner to that described above with respect to the thermal assessment of Block 92, i.e., determining desirable performance when the voltage responses 66 are within a predefined range and undesirable when outside the predefined range.

In response to Block 120 determining undesirable performance, Block 122 relates to concluding the undesirable performance in Block 98 to have resulted from inadequate TIM 46 wet-out. Because the undesirable performance occurred without reliance on the battery pack cold plate 42, the TIM 46 wet-out may be assumed to be the source. In response to Block 120 determining desirable performance, Block 124 relates to concluding the undesirable performance in Block 98 to have resulted from inadequate operation of the battery cold plate 42. Because the desirable performance in Block 120 occurred without reliance on the battery pack cold plate 42, the battery cold plate 42 may be assumed to be the source. Returning to Block 114, Block 128 relates to determining the thermal cycling to have been previously undertaken with the auxiliary cold plate 78, i.e., that the undesirable determination in Block 98 occurred without the battery cold plate 42 thermally cycling the battery pack 12. Block 130 relates to a battery cold plate assessment whereby the battery pack cold plate 42 may be used instead of the previously used auxiliary cold plate 78 to thermally cycled the battery pack 12. The voltage responses 66 of the battery cells 28 thereafter to the test load 88 may be determined, which may occur without intervention of the auxiliary cold plate 78.

The battery cold plate assessment may determine the performance to be desirable or undesirable in a similar manner to that described above with respect to the thermal assessment of Block 92, i.e., determining desirable performance when the voltage responses 66 are within a predefined range and undesirable when outside the predefined range. In response to Block 130 determining desirable performance, Block 122 relates to concluding the desirable performance in Block 98 to have resulted from inadequate TIM 46 wet-out due to the undesirable performance persisting when both of the battery and auxiliary cold plates 42, 78 were used for thermal cycling. In response to Block 130 determining undesirable performance, Block 124 relates to concluding the undesirable performance in Block 98 to have resulted at least from inadequate operation of the battery pack cold plate 42 due to the undesirable performance persisting in response to thermally cycling being performed by both of the battery pack and auxiliary cold plates 42, 78.

The terms “comprising”, “including”, and “having” are inclusive and therefore specify the presence of stated features, steps, operations, elements, or components, but do not preclude the presence or addition of one or more other features, steps, operations, elements, or components. Orders of steps, processes, and operations may be altered when possible, and additional or alternative steps may be employed. As used in this specification, the term “or” includes any one and all combinations of the associated listed items. The term “any of” is understood to include any possible combination of referenced items, including “any one of” the referenced items. “A”, “an”, “the”, “at least one”, and “one or more” are used interchangeably to indicate that at least one of the items is present. A plurality of such items may be present unless the context clearly indicates otherwise. All numerical values of parameters (e.g., of quantities or conditions), unless otherwise indicated expressly or clearly in view of the context, including the appended claims, are to be understood as being modified in all instances by the term “about” whether or not “about” actually appears before the numerical value. A component that is “configured to” perform a specified function is capable of performing the specified function without alteration, rather than merely having potential to perform the specified function after further modification. In other words, the described hardware, when expressly configured to perform the specified function, is specifically selected, created, implemented, utilized, programmed, and/or designed for the purpose of performing the specified function.

While various embodiments have been described, the description is intended to be exemplary, rather than limiting and it will be apparent to those of ordinary skill in the art that many more embodiments and implementations are possible that are within the scope of the embodiments. Any feature of any embodiment may be used in combination with or substituted for any other feature or element in any other embodiment unless specifically restricted. Accordingly, the embodiments are not to be restricted except in light of the attached claims and their equivalents. Also, various modifications and changes may be made within the scope of the attached claims. Although several modes for carrying out the many aspects of the present teachings have been described in detail, those familiar with the art to which these teachings relate will recognize various alternative aspects for practicing the present teachings that are within the scope of the appended claims. It is intended that all matter contained in the above description or shown in the accompanying drawings shall be interpreted as illustrative and exemplary of the entire range of alternative embodiments that an ordinarily skilled artisan would recognize as implied by, structurally and/or functionally equivalent to, or otherwise rendered obvious based upon the included content, and not as limited solely to those explicitly depicted and/or described embodiments.

What is claimed is:

1. A method for assessing performance of a thermal management system configured for thermally managing a battery pack of an electric vehicle, comprising:
determining a test load to be applied to a plurality of battery cells included as part of the battery pack;
determining a voltage response of the battery cells while subjected to the test load; and
generating a thermal assessment based on the voltage response, the thermal assessment representing capabilities of the thermal management system to thermally manage the battery pack.

2. The method according to claim 1, further comprising:
generating a resistivity profile for the battery cells according to the voltage response; and
generating the thermal assessment to indicate a wet-out for the battery pack to be desirable when the resistivity profile is within a resistivity response range and undesirable when outside of the resistivity response range, the wet-out characterizing thermal coupling via a thermal interface material (TIM) between the battery cells and a cold plate of the battery pack.

3. The method according to claim 1, further comprising:
the voltage response including a voltage measurement for each of the battery cells, the voltage measurement representing voltage sensed across the corresponding battery cell while subjected to the test load.

4. The method according to claim 3, further comprising:
the thermal assessment indicating performance of the thermal management system to be desirable when each of the voltage measurements are within the voltage response range and to be undesirable when at least one of the voltage measurements are outside of the voltage response range.

5. The method according to claim 3, further comprising:
the thermal assessment indicating performance of the thermal management system to be outside of a desired range in response to a voltage delta between one or more of the voltage measurements exceeding a threshold.

6. The method according to claim 3, further comprising:
the thermal assessment indicating performance of the thermal management system to be desirable when each of the voltage measurements are within a voltage response range and undesirable when one or more of the voltage measurements are outside of the voltage response range.

7. The method according to claim 1, further comprising:
thermally cycling the battery pack prior to applying the test load, the thermal cycling heating or cooling the battery pack from a first temperature to a second temperature; and
applying the test load while a temperature of the battery pack is within a predefined range of the second temperature.

8. The method according to claim 7, further comprising:
controlling coolant flow through a cold plate of the battery pack to thermally cycle the battery pack.

9. The method according to claim 7, further comprising:
controlling coolant flow through an auxiliary cold plate thermally coupled to a cold plate of the battery pack to thermally cycle the battery pack.

10. The method according to claim 7, further comprising:
before applying the test load, verifying the battery pack has reached the second temperature with a thermistor of the battery pack, the thermistor configured for measuring the temperature according to a temperature varying resistive element.

11. The method according to claim 1, further comprising:
applying the test load and measuring the voltage response with a cell monitoring unit (CMU) of the battery pack.

12. The method according to claim 11, further comprising:
applying the test load and measuring the voltage response as part of an end-of-line test performed before the battery pack is installed within the electric vehicle.

13. The method according to claim 11, further comprising:
applying the test load and measuring the voltage response as part of an in-vehicle test performed after the battery pack is installed within the electric vehicle.

14. The method according to claim 1, further comprising:
generating the test load as a direct current (DC) pulse.

15. The method according to claim 14, further comprising:
generating the DC pulse with an amplitude of approximately 300-500 amperes and a duration of approximately 15-45 seconds.

16. A method for assessing performance of a thermal management system configured for thermally managing a battery pack, comprising:
determining a test load to be applied to one or more battery groups included as part of the battery pack, each of the battery groups including one or more battery cells;
determining a voltage response of the battery groups while subjected to the test load; and
generating a thermal assessment based on the voltage response, the thermal assessment indicating a performance of the thermal management system to be desirable when the voltage response is within a voltage response range and to be undesirable when the voltage response outside of the voltage response range.

17. The method according to claim 16, further comprising:
thermally cycling the battery pack prior to applying the test load, the thermal cycling heating or cooling the battery pack from a first temperature to a second temperature; and
applying the test load while a temperature of the battery pack is within a predefined range of the second temperature.

18. The method according to claim 17, further comprising:
the voltage response including a voltage measurement for each of the battery cells, the voltage measurement representing voltage sensed across the corresponding battery cell while subjected to the test load;
determining a delta voltage according to a difference between a maximum measurement and a minimum measurement of the voltage measurements; and
determining the performance to be desirable when the voltage delta is within the voltage response range and determining the performance to be undesirable when the voltage delta is outside of the voltage response range.

19. The method according to claim 17, further comprising:
the voltage response including a voltage measurement for each of the battery cells, the voltage measurement representing voltage sensed across the corresponding battery cell while subjected to the test load; and
determining the performance to be desirable when each of the voltage measurements are within the voltage response range and determining the performance to be undesirable when at least one of the voltage measurement is outside of the voltage response range.

20. A method for assessing performance of a thermal management system configured for thermally managing a battery pack, the battery pack including a thermal interface material (TIM) for thermally coupling the battery pack to a cold plate, comprising:
determining a voltage response of the battery pack while subjected to a test load;
generating a resistivity profile for the battery pack according to the voltage response; and
indicating a wet-out for the battery pack to be desirable when the resistivity profile is within a resistivity response range and undesirable when outside of the resistivity response range, the wet-out characterizing thermal coupling of the TIM.
